(19) United States
(12) Patent Application Publication
(10) Pub. No.: US 2012/0218638 A1
(43) Pub. Date: Aug. 30, 2012

(54) METHOD FOR FORMING A DECORATIVE COATING, A COATING, AND USES OF THE SAME

(75) Inventors: Jarmo Maula, Espoo (FI); Tapani Alasaarela, Espoo (FI)

(73) Assignee: BENEQ OY, VANTAA (FI)

(21) Appl. No.: 13/505,607

(22) PCT Filed: Nov. 2, 2010
(86) PCT No.: PCT/FI10/50875

§ 371 Date: May 2, 2012

(30) Foreign Application Priority Data
Nov. 6, 2009 (FI) 20096153

(51) Int. Cl. G02B 5/28; G02B 5/22; C23C 16/40; C23C 16/44; B32B 33/00; C23C 16/18

(52) U.S. Cl. 359/585; 428/697; 427/162; 359/888; 359/738

(57) ABSTRACT

A decorative coating and a method for forming a decorative coating on a substrate (2). The decorative coating comprises an absorbing film (1) to attenuate the transmission of visible light through the coating. The method comprises the steps of bringing the substrate (2) into a reaction space, and depositing the absorbing film (1) on the substrate (2). Depositing the absorbing film (1) on the substrate comprises the steps of forming a preliminary deposit of transition metal oxide on the deposition surface and subsequently purging the reaction space, and treating the deposition surface with an organometallic chemical comprising first metal and subsequently purging the reaction space. The steps of forming the preliminary deposit and treating the deposition surface are alternately repeated to increase absorption of the absorbing film (1).

### FIELD OF THE INVENTION

The present invention relates to decorative coatings. Especially the present invention relates to a decorative coating and a method for forming a decorative coating comprising an absorbing film deposited by forming a deposit on a substrate and treating this deposit with a chemical. The invention also relates to uses of this method and of the decorative coating.

### BACKGROUND OF THE INVENTION

Decorative coatings are commonly employed on objects to modify their appearance. The surface of an object can be e.g. painted or metalized to change the color of the object. A dielectric thin-film structure can also be deposited on the surface of an object to impart a special appearance to the object by the reflectance spectrum of the structure which is a result of interference of light in the thin-film structure.

Optical interference structures, or thin-film filters or dichroic filters as they are often called, commonly employ transparent thin-films with different refractive indices. The reflectance and transmittance spectrum of the whole interference structure is dictated by interference of light reflected from the different boundaries between thin-films having different refractive indices. Due to this mechanism by which the reflectance and transmittance spectrum, i.e. the “color”, of an interference structure is formed, decorative coatings employing optical interference require accurate thickness control and good uniformity for the films in the structure incorporating the transparent thin-films. Otherwise a targeted color or appearance may not be achieved and/or the appearance may strongly depend on a position on the surface. An important part of many decorative coatings is a layer which absorbs light in the visible wavelength range.

An absorbing film as part of a decorative coating should possess an excellent thickness uniformity since thickness variations of the film may cause significant variations in the color appearance of the underlying object. For similar reasons the average thickness of the absorbing film should also be accurately controlled.

If a substrate reflects light, then the light which passes without reflection through an interference structure onto the substrate is reflected back from the substrate. This light mitigates the effect an interference structure has on the appearance of the substrate (i.e. the underlying object). Effective use of decorative coatings employing interference structures therefore requires an absorbing film on the substrate surface or integrated to the interference structure in which significant absorption of visible light would not otherwise occur. In light of the aforementioned operating mechanism of the interference structure it will be appreciated that the absorbing film should also be as uniform as possible and as conformal as possible.

A shortcoming in the methods of the prior art to fabricate a decorative coating is that surfaces of complex three dimensional (3D) objects can not be uniformly or conformally coated with the known methods.

For instance, U.S. Pat. No. 7,270,895 discloses an article having a layer coating with a dark color. Methods disclosed to form the coating in this publication are cathodic arc evaporation (CAE), sputtering, and PVD. A problem with these coating methods is their poor ability to uniformly and homogeneously coat non-planar surfaces and substrates with complex shapes. This is especially detrimental in decorative coating applications where the coating is often intended to provide a specific appearance uniformly over the entire surface of the substrate.

Chromium oxide, Cr₂O₃, is a well known material that may exhibit dark grey color tone. This material has been widely used and fabrication methods for chromium oxide are disclosed in e.g. U.S. Pat. No. 7,147,794. The methods for depositing chromium oxide are not able to produce films with uniform thickness and uniform optical properties over non-planar surfaces of e.g. three dimensional (3D) objects with complex shapes.

The inventors have identified a need for a method to fabricate an absorbing film in decorative coatings uniformly, homogeneously, and conformally, even over non-planar surfaces of 3D objects of various shapes.

### PURPOSE OF THE INVENTION

A purpose of the present invention is to solve the aforementioned technical problems of the prior art by providing a new type of decorative coating, a method for forming a decorative coating on a surface of a substrate, and uses of the same.

### SUMMARY OF THE INVENTION

The method according to the present invention is characterized by what is presented in claim 1.

The decorative coating according to the present invention is characterized by what is presented in claim 14.

The use according to the present invention is characterized by what is presented in claim 18 or 19.

A method according to the present invention relates to forming a decorative coating on a substrate. The decorative coating comprises an absorbing film to attenuate the transmission of visible light through the coating. The method comprises the steps of bringing the substrate into a reaction space, and depositing the absorbing film on the substrate. Depositing the absorbing film on the substrate comprises the steps of forming a preliminary deposit of transition metal oxide on the deposition surface and subsequently purging the reaction space, and treating the deposition surface with an organometallic chemical comprising first metal such that at least a portion of the organometallic chemical reacts with at least part of the preliminary deposit and subsequently purging the reaction space, to form oxide comprising oxygen, first metal and transition metal. The steps of forming the preliminary deposit and treating the deposition surface are alternately repeated to increase absorption of the absorbing film.

A decorative coating according to the present invention on a substrate comprises an absorbing film to attenuate the transmission of visible light through the coating. The absorbing film comprises oxygen, first metal and transition metal. The film is formed by forming a preliminary deposit of transition metal oxide on the deposition surface and subsequently purging the reaction space, and treating the deposition surface with an organometallic chemical comprising first metal such that at least a portion of the organometallic chemical reacts with at least part of the preliminary deposit and subsequently purging the reaction space, to form oxide comprising oxygen, first metal and transition metal. The steps of forming the preliminary deposit and treating the deposition surface are alternately repeated to increase absorption of the absorbing film.

It is emphasized that the expression “deposit” should be understood in this specification as referring to a very small amount of material, e.g. to a layer with a thickness of below a few monolayers, in which atoms may not be organized to a specific phase such that the advantages of the invention could be achieved. It was observed that only when the steps of forming the preliminary deposit and treating the deposition surface with an organometallic chemical are carried out such that a film of oxide is formed on the substrate can this film of material possess the advantageous properties. The steps of forming the preliminary deposit and treating the deposition surface are alternately repeated to increase absorption of the absorbing film by increasing the thickness of the film. Hence the expression “film” should be understood as a structure in which the volume of material is sufficient to enable atoms in the film to organize in a phase which possesses the high absorption coefficient.

It is obvious, but nevertheless also emphasized, that the steps of “forming a preliminary deposit” and “treating the deposition surface” do not have to be performed successively but a method according to the present invention may include other steps in between forming the preliminary deposit and treating the deposition surface. The other steps in between “forming a preliminary deposit” and “treating the deposition surface” may include e.g. growing deposit of other material on the deposition surface such that reaction of the preliminary deposit with the organometallic chemical is not entirely prevented.

The steps of forming the preliminary deposit and treating the deposition surface are performed alternately, i.e. these steps do not markedly overlap in time. This means that the chemicals responsible for the growth of the preliminary deposit are not present in large amounts in the same space at the same time with the chemicals responsible for treating the deposition surface, i.e. the organometallic chemical. Hence the formation process of the preliminary deposit does not markedly affect the treatment process of the deposition surface, and vice versa. It will however be obvious for a skilled person that in case the aforementioned two steps are performed in e.g. the same reaction space, residuals of chemicals from the previous step may be present a long time in the reaction space. These residuals may be able affect the following process steps to some extent even though the steps do not markedly overlap in time. In this context alternation of the two steps is intended to ensure that chemical reactions governing the formation of the film of oxide predominantly occur on or close to the deposition surface and not in the gas phase farther away from the deposition surface. Unless otherwise stated, this definition also holds for other process steps discussed in this specification which are intended to be alternately performed.

In this specification unless otherwise stated the expression “transparent” should be understood as essentially transparent to visible light, and the expression “absorption coefficient” should be understood as absorption coefficient for light.

In this specification, unless otherwise stated, the expression “decorative coating” should be understood as any coating which serves to give a specific color appearance to the substrate or to the environment as viewed through the coating, including a grayscale appearance.

The method according to the present invention is used in one embodiment of the invention for forming a decorative coating on a substrate, the decorative coating comprising the absorbing film to attenuate the transmission of visible light through the coating.

The decorative coating of the present invention is used in one embodiment of the invention on a substrate, the decorative coating comprising an absorbing film to attenuate the transmission of visible light through the coating.

The method of the present invention surprisingly results in a film which, in view of its thickness, is highly absorbing in the visible wavelength band of 400-750 nm of the electromagnetic spectrum. The resulting absorbing film also possesses good thickness uniformity and conformal surface coverage, even over complex non-planar surfaces of three dimensional (3D) objects. Among other benefits, this prevents the non-homogenous color appearance caused by non-uniform films formed with methods of the prior art and facilitates e.g. the optical design of decorative coatings employing this absorbing film formed according to the method of the present invention.

Without limiting the invention to any specific theory about why the method of the present invention results in the aforementioned advantages, the following theory should nevertheless be considered. When the preliminary deposit of transition metal oxide reacts with the organometallic chemical, the first metal of the organometallic chemical gets incorporated as part of the deposit such that optically absorbing oxide is formed. The chemical reactions resulting in the formation of the optically absorbing phase of the oxide comprising oxygen, transition metal and the first metal are not entirely known at this point, but experimental results revealed that these reactions surprisingly provide oxide which has a high absorption coefficient for visible light. A film of this absorbing oxide can be formed by alternately repeating the steps of forming the preliminary deposit and treating the formed deposit. This film possesses the advantageous properties discussed above. Furthermore, the alternate growth of the preliminary deposit and the treating of this deposit lead to an at least partly self-limiting growth mechanism predominantly governed by adsorption reactions on the deposition surface, which results in the advantageous conformality of the film. This film also has a thickness profile which is relatively uniform even over large surface areas compared to films which have been obtained using methods of the prior art.

In one embodiment of the present invention, forming the preliminary deposit of transition metal oxide comprises in any order the alternating steps of, a) exposing the deposition surface to an oxygen containing chemical such that at least a portion of the oxygen containing chemical adsorbs onto the deposition surface, and subsequently purging the reaction space, and b) exposing the deposition surface to a transition metal chemical such that at least a portion of the transition metal chemical gets adsorbed onto the deposition surface, and subsequently purging the reaction space.

In another embodiment of the invention treating the deposition surface with an organometallic chemical comprises c) exposing the deposition surface of the substrate to an organometallic chemical such that at least a portion of the organometallic chemical gets adsorbed onto the deposition surface, and subsequently purging the reaction space.

In another embodiment of the invention step a) comprises exposing the deposition surface to water, step b) comprises exposing the deposition surface to titanium tetrachloride, and step c) comprises exposing the deposition surface to trimethylaluminum.

In one embodiment of the invention the first metal is aluminum. In another embodiment of the invention the transition metal is titanium.

By suitably choosing the chemicals and the process parameters, especially the temperature of the substrate when the surface of the substrate is exposed to chemicals and the pressure inside the reaction space, the adsorption of chemicals onto the deposition surface, the growth of the preliminary deposit of transition metal oxide and the treatment of this preliminary deposit with the organometallic chemical, can be made essentially self-limiting. This further improves the thickness uniformity of the resulting film and conformality on the surface of 3D objects with complex shapes. Additionally the chemicals listed above are relatively inexpensive and the method of the invention can be carried out cost-effectively.

There exists many different sequences for performing the steps a), b) and c) of some embodiments of the present invention in a particular order, and some embodiments of the invention having a specific order for performing the steps a), b) and c) provide better results than other embodiments. In some other embodiments of the invention the steps a) and b) can be repeated a number of times to form the preliminary deposit before, in the step c), this preliminary deposit is exposed to the organometallic chemical. The invention does not limit the number of repetitions for the steps a) and b) before the step c).

When the chemicals responsible for film growth are alternately present in the reaction space the chemicals are not able to intermix and the growth of the absorbing film is predominantly governed by adsorption reactions on the deposition surface. The kinetics of these adsorption reactions are, on the other hand, governed predominantly by the properties of the deposition surface and not so much by the flow dynamics of the chemicals over the deposition surface and in the reaction space. In some embodiments of the invention this results in the absorbing film being very conformal and having a very uniform thickness essentially regardless of the shape of the substrate (or of the deposition surface). Additionally, the thickness of the film can be accurately controlled in these embodiments by the number of exposures as a given amount of material adsorbs during each exposure step.

In one embodiment of the invention the steps a), b), and c) are carried out in the order, first a), then b), then c), then b) again, and this sequence is repeated one or more times to increase the thickness of the film. In another embodiment of the invention the steps a), b), and c) are carried out in the order, first a), then b), then c), and this sequence is repeated one or more times to increase the thickness of the film. In yet another embodiment of the invention the steps a), b), and c) are carried out in the order, first a) and then b), this sequence is repeated one or more times, after which step c) is carried out. The material of the film in these embodiments of the invention exhibits relatively high electrical resistivity and good chemical stability when exposed to e.g. atmospheric conditions or to other potentially oxidizing conditions in which the film may be exposed to moisture and/or oxygen. The material of the film surprisingly also exhibits relatively uniform absorption spectra in the visible part of the electromagnetic spectrum, which results in a grey color tone.

As each exposure of the surface of the substrate to a chemical results in a portion of the chemical being adsorbed onto the surface of the substrate, the number of how many times the surface of the substrate is exposed to the chemicals can be utilized in some embodiments of the invention to control the thickness of the film. These methods of forming a film on a substrate therefore enable very accurately controlling the thickness of the film. Hence, the total absorption of light in the film, and therefore the darkness of the film, can be accurately controlled.

In one embodiment of the invention the steps a), b), and c) are each carried out one or more times for forming an absorbing film having a thickness between 1 nm to 2 μm on the substrate. When the thickness of the film of some embodiments of the invention is below 1 nm or above 2 μm the film is essentially transparent or opaque, respectively, to human eye. Therefore films falling within the range of 1 nm to 2 μm can be efficiently used as grayscale filters.

In one embodiment of the invention the pressure in the reaction space is between 0.1 mbar (0.1 hPa) and 100 mbar (100 hPa) when the surface of the substrate is exposed to chemicals. In another embodiment of the invention the temperature of the surface of the substrate is in the range of 150° C. to 600° C., preferably in the range of 200° C. to 500° C. and most preferably in the range of 250 to 450° C., when the surface of the substrate is exposed to chemicals.

In one embodiment of the invention the steps of forming the preliminary deposit and treating the deposition surface are alternately repeated less than 4000 times to form a thin absorbing film. The thin absorbing film of this embodiment can be easily deposited on e.g. lenses on which the thin film can be used e.g. as a relatively accurate grayscale filter.

In another embodiment of the invention the substrate is non-planar.

In one embodiment of the invention the method comprises the steps of, depositing a first transparent film having a first refractive index on the absorbing film by alternately exposing the deposition surface in the reaction space to different chemicals, such that at least a portion of the chemical which the surface is exposed to adsorbs onto the surface, and depositing a second transparent film having a second refractive index, different from the first refractive index, on the first transparent film by alternately exposing the deposition surface in the reaction space to different chemicals, such that at least a portion of the chemical which the surface is exposed to adsorbs onto the surface, to form a thin-film interference structure on the absorbing film. In another embodiment of the invention the coating comprises a first transparent film having a first refractive index on the absorbing film, and a second transparent film having a second refractive index, different from the first refractive index, on the first transparent film, to form a thin-film interference structure on the absorbing film. In these embodiments the absorbing film can be employed in the decorative coating in between a thin-film interference structure and the coated object (substrate), or within an interference structure, to attenuate the transmission of visible light through the coating.

In cases where the thin-film interference structure is viewed as being on top of the absorbing film the color of the object is predominantly determined by the reflectance properties of the interference structure. If the absorbing film is thin, allowing some part of the light to pass through the film, the absorbing film together with the thin-film interference structure determines the color appearance.

In one embodiment of the invention the substrate is essentially transparent in the visible part of the electromagnetic spectrum. In another embodiment of the invention the substrate is a lens. On a lens, in e.g. eyeglasses, a decorative coating of the present invention can be used to impart a special color appearance to the lens on one side while attenuating this color appearance on the other side to retain a natural viewing experience. I.e. the color of the lens on one side can be made different from the view-through color appearance on the other side.

The embodiments of the invention described hereinbefore may be used in any combination with each other. Several of the embodiments may be combined together to form a further embodiment of the invention. A method, a product or a use, to which the invention is related, may comprise at least one of the embodiments of the invention described hereinbefore.

### DETAILED DESCRIPTION OF THE INVENTION

In the following, the present invention will be described in more detail with exemplary embodiments by referring to the accompanying figures, in which

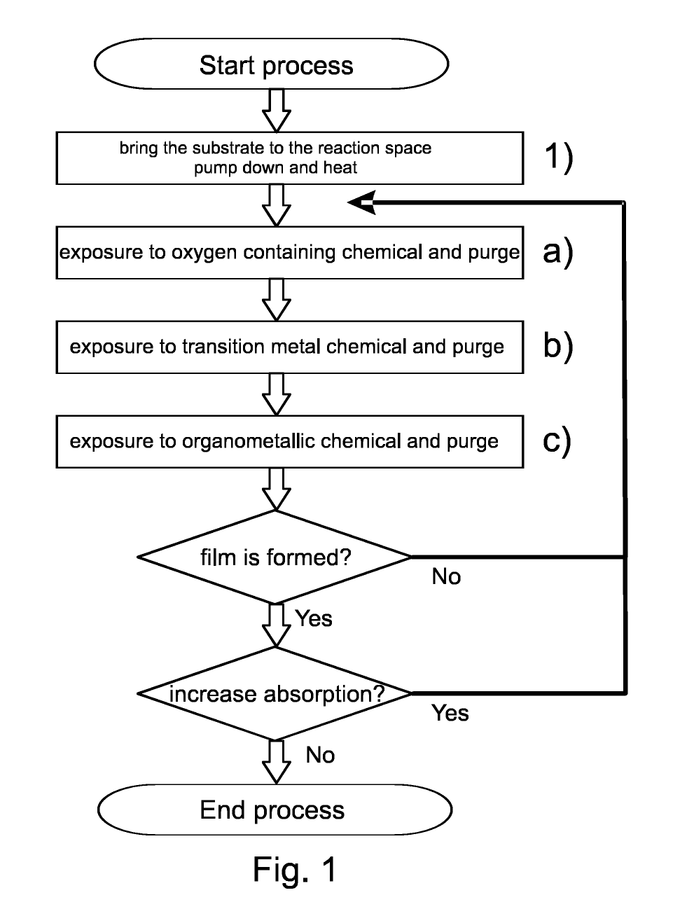

FIG. 1 is a flow-chart illustration of a method according to a first embodiment of the present invention,

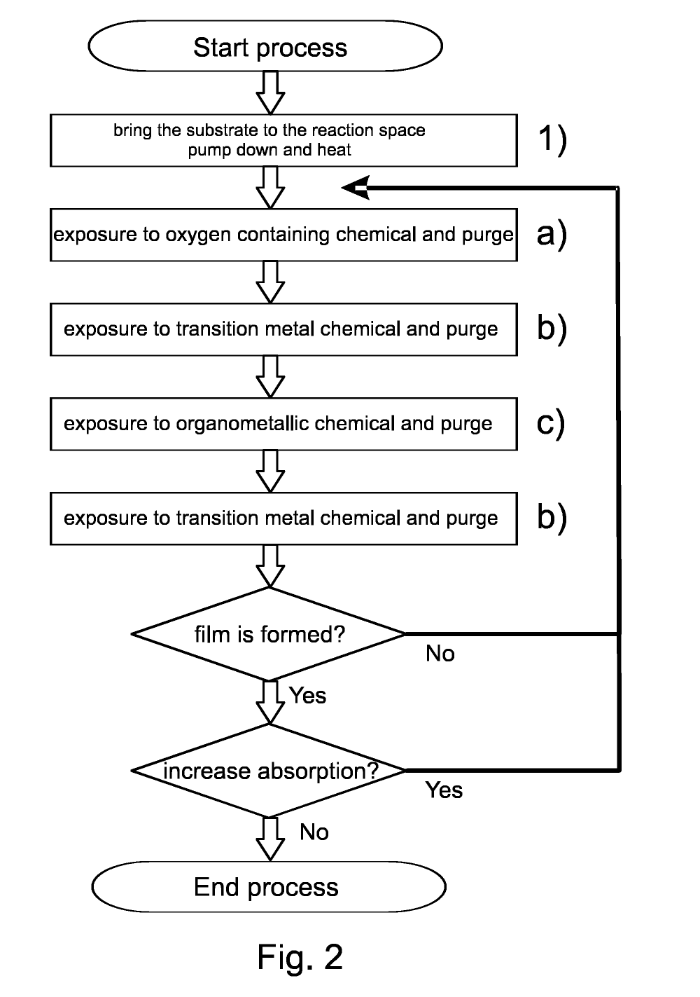

FIG. 2 is a flow-chart illustration of a method according to a second embodiment of the present invention,

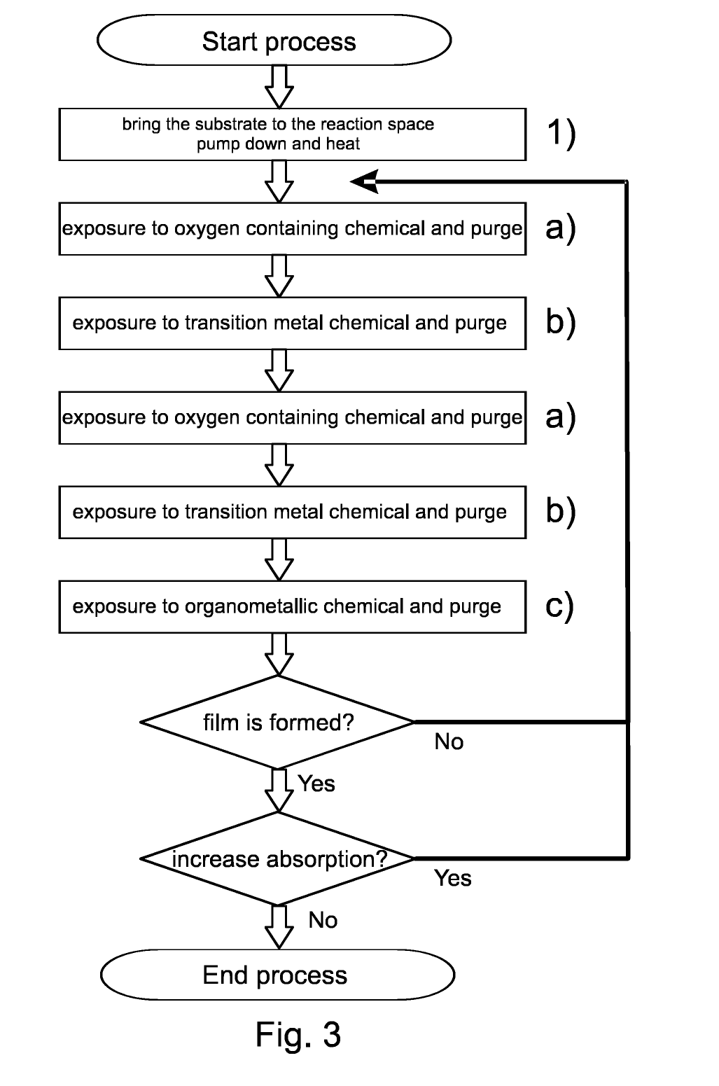

FIG. 3 is a flow-chart illustration of a method according to a third embodiment of the present invention,

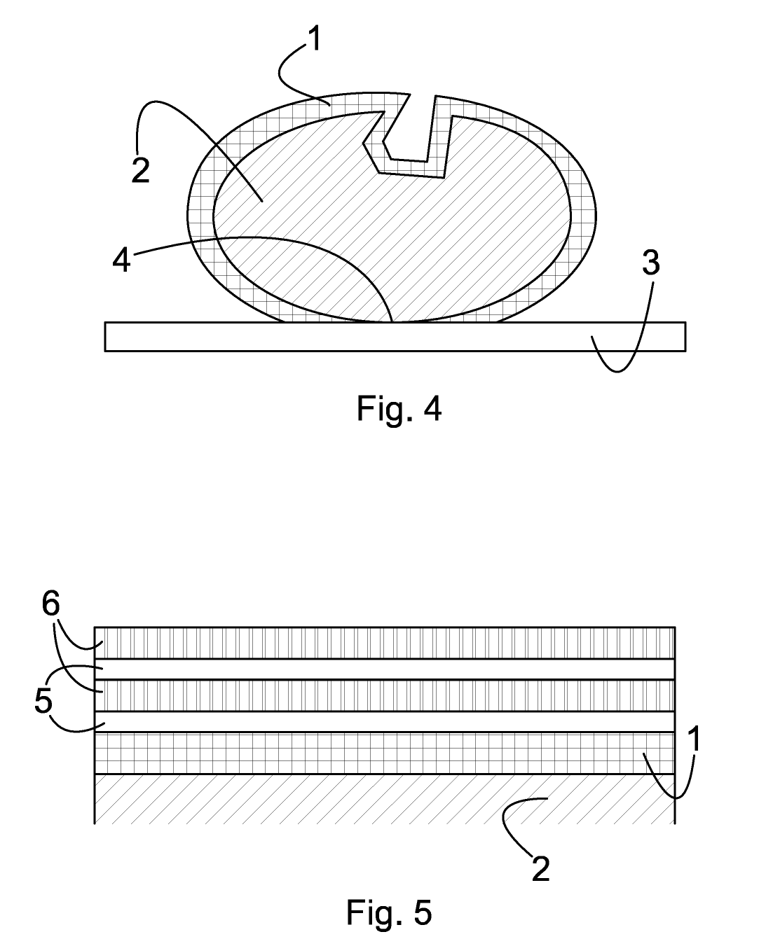

FIG. 4 schematically illustrates how the absorbing film formed according to one embodiment of the present invention conforms to the shape of the substrate,

FIG. 5 schematically illustrates a decorative coating structure according to one embodiment of the present invention,

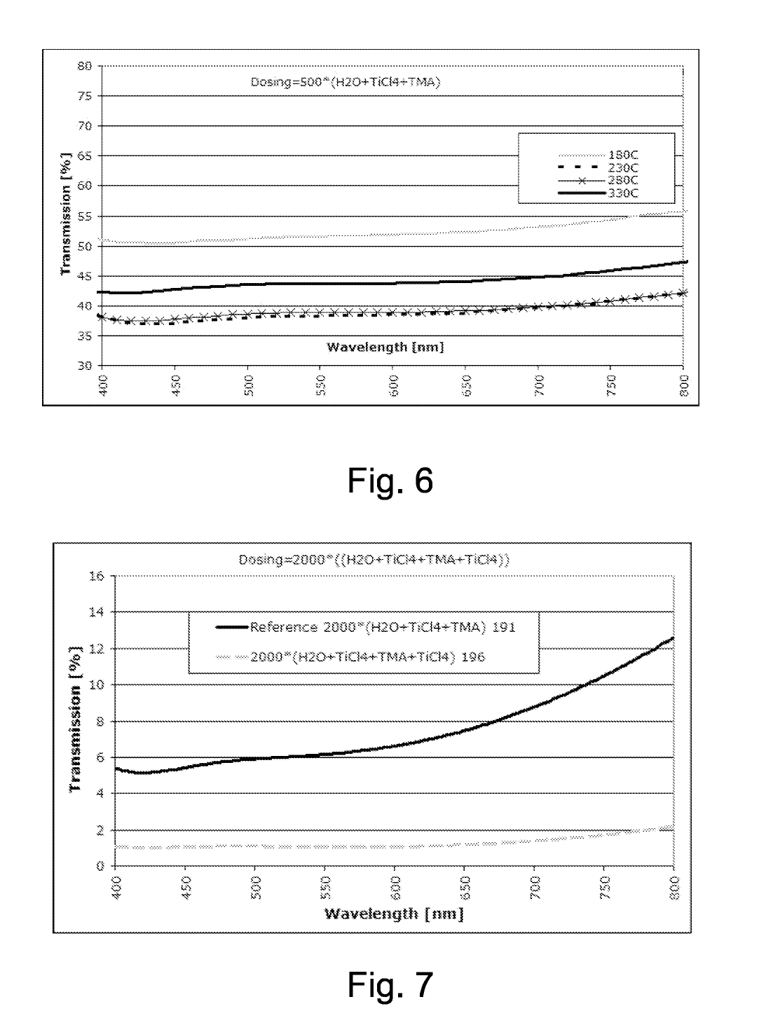

FIG. 6 presents data obtained from optical transmission measurements from an absorbing film formed according to the first embodiment of the present invention, and

FIG. 7 presents data obtained from optical transmission measurements from an absorbing film formed according to the second embodiment of the present invention.

The description below discloses some embodiments of the invention in such a detail that a person skilled in the art is able to utilize the invention based on the disclosure. Not all steps of the embodiments are discussed in detail, as many of the steps will be obvious for the person skilled in the art based on this specification.

Atomic Layer Deposition (ALD) is a method for depositing uniform and conformal thin-films over substrates of various shapes, even over complex 3D (three dimensional) structures. In ALD the coating is grown by alternately repeating, essentially self-limiting, surface reactions between a precursor and a surface to be coated. Therefore the growth mechanism in an ALD process is commonly not as sensitive as in other coating methods to e.g. the flow dynamics inside a reaction chamber which may be a source for non-uniformity, especially in coating methods relying on gas-phase reactions or in physical deposition methods, such as metal-organic chemical vapor deposition (MOCVD) or physical vapor deposition (PVD).

In an ALD process two or more different chemicals (precursors) are introduced to a reaction space in a sequential, alternating, manner and the chemicals adsorb on surfaces, e.g. on a substrate, inside the reaction space. The sequential, alternating, introduction of chemicals is commonly called pulsing (of chemicals). In between each chemical pulse there is commonly a purging period during which a flow of gas which does not react with the chemicals used in the process is introduced through the reaction space. This gas, often called the carrier gas, is therefore inert towards the chemicals used in the process and purges the reaction space from e.g. surplus chemical and by-products resulting from the adsorption reactions of the previous chemical pulse. This purging can be arranged also by other means, and the deposition method can be called by other names such as ALE (Atomic Layer Epitaxy), ALCVD (Atomic Layer Chemical Vapor Deposition), cyclic vapor deposition etc. The essential feature of these methods is to sequentially expose the deposition surface to precursors and to growth reactions of precursors essentially on the deposition surface.

A film can be grown by an ALD process by repeating several times a pulsing sequence comprising the aforementioned pulses containing the precursor material, and the purging periods. The number of how many times this sequence, called the “ALD cycle”, is repeated depends on the targeted thickness of the film, or coating.

The prior art discloses a wide range of materials that can be synthesized and deposited on a substrate by alternately exposing the surface of the substrate to different chemicals, in an ALD- or in an ALD-like process. Also many different apparatuses suitable for carrying out an ALD- or an ALD-like process are disclosed in the prior art. For example U.S. Pat. No. 6,824,816 discloses processes for depositing metal thin-films by ALD, and U.S. Pat. No. 6,174,377 describes deposition tools for ALD. A good review about the basics of ALD in general is the book; Atomic Layer Epitaxy, by T. Suntola et al., Blackie and Son Ltd., Glasgow, 1990.

The construction of a processing tool suitable for carrying out the methods in the following embodiments will be obvious for the skilled person in light of this specification. The tool can be e.g. a conventional ALD tool suitable for handling the chemicals discussed below. ALD tools (i.e. reactors) are disclosed in e.g. U.S. Pat. No. 4,389,973 and U.S. Pat. No. 4,413,022 which are included herein as references. Many of the steps related to handling such tools, such as delivering a substrate into the reaction space, pumping the reaction space down to a low pressure, or adjusting gas flows in the tool if the process is done at atmospheric pressure, heating the substrates and the reaction space etc., will be obvious for the skilled person. Also, many other known operations or features are not described here in detail nor mentioned, in order to emphasize relevant aspects of the various embodiments of the invention.

In this specification, unless otherwise stated, the term “the surface” or “deposition surface” is used to address the surface of the substrate or the surface of the already formed film on the substrate. Hence “the surface” or “deposition surface” changes during the method of forming a film on the substrate when chemicals get adsorbed onto the surface.

The exemplary embodiments of the present invention below begin by bringing the substrate into the reaction space (step 1)) of a typical reactor tool, e.g. a tool suitable for carrying out an ALD process. The reaction space is subsequently pumped down to a pressure suitable for forming the film, using e.g. a mechanical vacuum pump, or in the case of atmospheric pressure ALD systems and/or processes, flows are typically set to protect the deposition zone from the atmosphere. The substrate is also heated to a temperature suitable for forming the film by the used method. The substrate can be introduced to the reaction space through e.g. an airtight load-lock system or simply through a loading hatch. The substrate can be heated by e.g. resistive heating elements which also heat the entire reaction space. Step 1) may also include other preparation procedures, such as growing film on the substrate or otherwise preparing the substrate for subsequent process steps. The preparation procedures depend on the reactor tool or on the environment in which the tool is operated. The implementation of these procedures will be obvious for the skilled person in light of this specification.

In step 1) additional pre-treatment steps of the deposition surface are also possible. The deposition surface can be e.g. exposed to pre-treatment chemical which functionalizes the deposition surface. After the pre-treatment the growth process can proceed e.g. through alternate exposure of the deposition surface to the chemicals responsible for film growth in the steps a), b) and/or c). The functionalization of the deposition surface can be used to enable good control of film growth during the first stages of the growth process.

After the substrate and the reaction space have reached the targeted temperature and other conditions suitable for deposition an alternate exposure of the deposition surface to different chemicals is started, to form preliminary deposit of transition metal oxide. The preliminary deposit can in some other embodiments of the invention be formed by methods such as CVD or PVD which do not employ alternating exposure of the deposition surface to different chemicals.

The surface of the substrate is suitably exposed to chemicals in their gaseous form. This can be realized by first evaporating the chemicals in their respective source containers which may or may not be heated depending on the properties of the chemical itself. The evaporated chemical can be delivered into the reaction space by e.g. dosing it through the pipe-work of the reactor tool comprising flow channels for delivering the vaporized chemicals into the reaction space. Controlled dosing of vapor into the reaction space can be realized by valves installed in the flow channels or other flow controllers. These valves are commonly called pulsing valves in a system suitable for ALD. Also other mechanisms of bringing the substrate into contact with a chemical inside the reaction space may be conceived. One alternative is to make the surface of the substrate (instead of the vaporized chemical) move inside the reaction space such that the substrate moves through a region occupied by a gaseous chemical.

A typical ALD reactor comprises a system for introducing carrier gas, such as nitrogen or argon into the reaction space such that the reaction space can be purged from surplus chemical and reaction by-products before introducing the next chemical into the reaction space. This feature together with the controlled dosing of vaporized chemicals enables alternately exposing the surface to chemicals without significant intermixing of different chemicals in the reaction space or in other parts of the reactor. In practice the flow of carrier gas is commonly continuous through the reaction space throughout the deposition process and only the various chemicals are alternately introduced to the reaction space with the carrier gas. Obviously, purging of the reaction space does not necessarily result in complete elimination of surplus chemicals or reaction by-products from the reaction space but residues of these or other materials may always be present.

Following the step of various preparations (step 1) discussed above), in a first embodiment of the present invention, step a) is carried out i.e. the surface of the substrate is exposed to an oxygen containing chemical. This first embodiment is presented in FIG. 1. Exposure of the surface to the oxygen containing chemical results, in suitable process conditions discussed below, in the adsorption of a portion of the oxygen containing chemical onto the surface. After purging of the reaction space the surface is exposed to a transition metal chemical (step b)), some of which in turn gets adsorbed onto the surface resulting from step a). Step a) followed by step b) results in the formation of preliminary deposit of transition metal oxide on the deposition surface. After the purging phase of step b) the resulting surface is exposed to an organometallic chemical in step c), i.e. the preliminary deposit is treated with the organometallic chemical. This treatment results in some of the organometallic chemical getting adsorbed onto the deposition surface, and eventually the first metal in the organometallic chemical is incorporated to the deposit. The reaction space is subsequently purged. As explained, each exposure step a), b) or c) results in formation of additional deposit on the surface as a result of adsorption reactions of the corresponding chemical with the deposition surface. Thickness of the deposit on the substrate can be increased by repeating the steps a), b), and c) in this order as presented by the flow-chart of FIG. 1. When a sufficient thickness for the deposit is reached, the deposit forms the film of oxide material comprising oxygen, first metal from the organometallic chemical and transition metal. This film of oxide material possesses the advantageous properties discussed. The thickness of the film is increased until a targeted level of absorption is reached, after which the alternate exposures are stopped and the process is ended.

Following the step of various preparations (step 1) discussed above), in a second embodiment of the present invention, step a) is carried out i.e. the surface of the substrate is exposed to an oxygen containing chemical. This second embodiment is presented in FIG. 2. Exposure of the surface to the oxygen containing chemical results, in suitable process conditions discussed below, in the adsorption of a portion of the oxygen containing chemical onto the surface. After purging of the reaction space the surface is exposed to a transition metal chemical (step b)) some of which in turn gets adsorbed onto the surface resulting from step a). Step a) followed by step b) results in the formation of preliminary deposit of transition metal oxide on the deposition surface. After the purging phase of step b) the resulting surface is exposed to an organometallic chemical in step c), i.e. the preliminary deposit is treated with the organometallic chemical. This treatment results in some of the organometallic chemical getting adsorbed onto the deposition surface, and eventually the first metal in the organometallic chemical is incorporated to the deposit. The reaction space is subsequently purged after which the resulting surface is again exposed to the transition metal chemical and the reaction space is subsequently purged, i.e. step b) is repeated. As explained, each exposure step a), b) or c) results in formation of additional deposit on the surface as a result of adsorption reactions of the corresponding chemical with the deposition surface. Thickness of the deposit on the substrate can be increased by repeating the steps a), b), c), and b) in this order as presented by the flow-chart of FIG. 2. When a sufficient thickness for the deposit is reached, the deposit forms the film of oxide material comprising oxygen, first metal from the organometallic chemical and transition metal. This film of oxide material possesses the advantageous properties discussed. The thickness of the film is increased until a targeted level of absorption is reached, after which the alternate exposures are stopped and the process is ended.

Following the step of various preparations (step 1) discussed above), in a third embodiment of the present invention, step a) is carried out i.e. the surface of the substrate is exposed to an oxygen containing chemical. This third embodiment is presented in FIG. 3. Exposure of the surface to the oxygen containing chemical results, in suitable process conditions discussed below, in the adsorption of a portion of the oxygen containing chemical onto the surface. After purging of the reaction space the surface is exposed to a transition metal chemical (step b)), some of which in turn gets adsorbed onto the surface resulting from step a). Step a) followed by step b) results in the formation of preliminary deposit of transition metal oxide on the deposition surface. To increase the thickness of the preliminary deposit step a) and step b) are subsequently repeated once before step c) is carried out in this embodiment of the present invention. After the purging phase of step b) the resulting surface is exposed to an organometallic chemical in step c), i.e. the preliminary deposit is treated with the organometallic chemical. This treatment results in some of the organometallic chemical getting adsorbed onto the deposition surface, and eventually the first metal in the organometallic chemical is incorporated to the deposit. The reaction space is subsequently purged. As explained, each exposure step a), b) or c) results in formation of additional deposit on the surface as a result of adsorption reactions of the corresponding chemical with the deposition surface. Thickness of the deposit on the substrate can be increased by repeating the steps a), b), a), b), and c) in this order as presented by the flow-chart of FIG. 3. When a sufficient thickness for the deposit is reached, the deposit forms the film of oxide material comprising oxygen, first metal from the organometallic chemical and transition metal. This film of oxide material possesses the advantageous properties discussed. The thickness of the film is increased until a targeted level of absorption is reached, after which the alternate exposures are stopped and the process is ended.

In the discussed embodiments, the shortest repeating sequence of exposure steps is called a pulsing sequence; the pulsing sequence of the first embodiment of FIG. 1 is a), b), c), the pulsing sequence of the second embodiment of FIG. 2 is a), b), c), b), and the pulsing sequence of the third embodiment of FIG. 3 is a), b), a), b), c). The chemical to which the substrate is exposed can be different in each exposure step of the process. In the first embodiment of FIG. 1, for example, the oxygen containing chemical in step a) can be different each time the pulsing sequence a), b), c) is repeated. This applies to other embodiments of the invention as well.

The methods disclosed above may not provide a full monolayer of deposit in one deposition cycle. After each deposition cycle, the deposition surface has open nucleation sites. A full monolayer of deposit may require even 3 to 10 deposition cycles depending on the details of the process. Scientific literature uses e.g. the term “steric hindrance” to describe the mechanism which results in this sub-monolayer coverage per one deposition cycle. There may however also be other reasons to not getting full monolayer coverage after each deposition cycle. This, among other reasons, opens up the possibility to deposit, in some other embodiments of the invention, additional material on the preliminary deposit before treating the preliminary deposit with the organometallic chemical in step c), provided that the organometallic chemical of step c) can at least partly react with the material, the preliminary deposit, created by e.g. performing, possibly repeatedly, steps a) and b).

To form a film of material possessing the advantageous properties discussed above from the deposit, the preliminary deposit may have to be in some embodiments of the invention alternately formed on the deposition surface and treated by the organometallic chemical several times. In the embodiments of the invention presented in FIG. 1, FIG. 2 and FIG. 3, this is carried out by repeating the deposition cycle one or more times, i.e. by performing the cycle two or more times.

The embodiments of the present invention result in a relatively uniform absorbing film 1 conforming to the shape of the substrate 2. This is schematically illustrated in FIG. 4 where the substrate 2 is placed in a reaction space such that the substrate 2 rests on a wall 3 of the reaction space. As illustrated by FIG. 4, the wall 3 masks part of the substrate 2 during the deposition process such that the absorbing film 1 is not able to grow on the masked areas 4 of the substrate. Also other areas of a substrate 2 can be mechanically masked to deposit the absorbing film 1 on selective areas of a substrate 2.

FIG. 5 presents a decorative coating structure on a substrate 2 according to one embodiment of the invention. In the method to fabricate this structure the absorbing film 1 is first formed on the substrate 2. Subsequently a structure comprising thin-films with a lower refractive index 5 and thin-films with a higher refractive index 6 are formed on the absorbing film 1. The low refractive index films 5 and the high refractive index films 6 alternate in the structure and form an optical interference structure whose reflectance spectrum can be tailored by e.g. modifying the thickness of each film 5, 6 in the interference structure. In this structure of FIG. 5 the absorbing film 1 is used to optically isolate the substrate 2 and the interference structure between which the absorbing film 1 is formed. As only little visible light is able to penetrate the absorbing film 1 the color of the substrate 2 does not markedly affect the color appearance of the coated substrate 2 and the color is predominantly determined by the interference structure.

It will be obvious for a person skilled in the art that the number of films 5, 6 may vary according to design and according to the targeted reflectance spectrum. In some embodiments of the invention it is possible to even use a single layer design with only one film 5, 6 on the absorbing film 1. In this case interference occurs between light reflected from the surface of the structure and light reflected from the interface between the one film 5, 6 and the absorbing film 1. It will also be obvious for a skilled person that many different materials can be used even in a single interference structure for the films with the higher and lower refractive index 5, 6 to achieve the required interference effect. In some embodiments of the invention the decorative coating comprising the absorbing film 1 can e.g. be employed as a grayscale filter on a lens. When the decorative coating comprises the absorbing film 1 and a thin-film interference structure on the first side of the lens substrate 2, such that the absorbing film 1 resides in between the lens and the thin-film interference structure (as in FIG. 5), the thin-film interference structure can be used to give a specific color to the lens while the absorbing film 1 absorbs visible light such that the coloring effect of the thin-film interference structure is attenuated on the second side of the lens. In this way the decorative coating enables the lens to be colored from the first side using a thin-film interference structure, or any other film suitable for applying a color to the lens, while the absorbing film 1 ensures that the viewer on the second side of the lens does not see the coloring. Also, with a similar structure a specific coloring observed from the second side of the lens, e.g. yellow, can be made different from the coloring observed from the first side of the lens. Thus the structure can be designed to impart different colors on the different sides of a lens or other transparent substrates. This can be employed to adjust the view-through color of the lens to better suite e.g. the human eye or specific lighting conditions.

In one embodiment of the invention the substrate 2 can in itself be a thin-film interference structure on a transparent object such as a lens. The absorbing film 1 can then be deposited on the interference structure. In this embodiment the lens can be used such that the absorbing film 1 is closer to the viewer than the interference structure, and the decorative coating enables, in this case also, the lens to be made to look colored on the first side using a thin-film interference structure, while the absorbing film 1 ensures that the viewer on the second side of the lens does not see the coloring. Also, with a similar structure a specific coloring observed from the second side of the lens, e.g. yellow, can be made different from the coloring observed from the first side of the lens. Thus the structure can be designed to impart different colors on the different sides of a lens or other transparent substrates. This can be employed to adjust the view-through color of the lens to better suite e.g. the human eye or specific lighting conditions.

In some other embodiments of the invention the absorbing film 1 can be deposited on all sides of a transparent substrate 2, e.g. on both sides of an essentially planar lens. This enables using a thinner absorbing film to achieve the same degree of absorption than in a situation where the transparent substrate is only coated from one side. The absorbing film 1 or the thin-film interference structure may also, in some embodiments of the invention, be coated with an anti-reflection (AR) coating or with a hard coating to protect the underlying structure.

In some embodiments of the invention the absorbing film 1, the thin-films with a lower refractive index 5 and the thin-films with a higher refractive index 6 of FIG. 5 are formed in a reactor suitable for ALD in a single process without ejecting the substrate 2 from the reactor during the deposition of the structure.

By suitably choosing the chemicals and the process parameters utilized to deposit the absorbing film 1, the adsorption reactions responsible for film-growth exhibit very self-limiting characteristics, and the conformality and the homogeneity of the absorbing film 1 can be further improved. The following examples describe in detail how the absorbing film 1 can be grown on the substrate 2.

### EXAMPLE 1

Using different processing temperatures absorbing films were formed on substrates according to the first embodiment of the invention (see FIG. 1). Visibly essentially transparent D263T glass substrates with a thickness of 0.3 mm (available from Schott AG, Germany) were first inserted inside the reaction space of a P400 ALD batch tool (available from Beneq OY, Finland). The substrates were planar to enable reliable optical transmission measurements. The substrates were positioned inside the reaction space such that both sides of the substrate glass were exposed (i.e. not masked) to the surrounding reaction space. In this example the carrier gas discussed above, and responsible for purging the reaction space, was nitrogen (N₂).

After preparations for loading the substrates into the ALD tool, the reaction space of the ALD tool was pumped down to underpressure and a continuous flow of carrier gas was set to achieve the processing pressure of about 1 mbar (1 hPa) and the substrates were subsequently heated to the processing temperature. The temperature was stabilized to the processing temperature inside the reaction space by a computer controlled heating period of four to six hours.

After the processing temperature was reached and stabilized, the method moved from step 1) to the first exposure step, step a), according to FIG. 1. The pulsing sequence of a), then b), then c) was carried out once and then repeated 499 times before the process was ended and the substrates were ejected from the reaction space and from the ALD tool.

Exposure of the surface of the substrate to a specific chemical was carried out by switching on the pulsing valve of the P400 ALD tool controlling the flow of the precursor chemicals into the reaction space. Purging of the reaction space was carried out by closing the valves controlling the flow of precursor chemicals into the reaction space, and thereby letting only the continuous flow of carrier gas flow through the reaction space.

The pulsing sequence in this example was in detail as follows; 0.6 s exposure to H₂O, 1.5 s purge, 0.4 s exposure to TiCl₄, 2.0 s purge, 0.5 s exposure to trimethylaluminum, 2.0 s purge. An exposure time and a purge time in this sequence signify a time a specific pulsing valve for a specific chemical was kept open and a time all the pulsing valves for chemicals were kept closed, respectively.

In this example four different films formed at different processing temperatures, at 180° C., at 230° C., at 280° C. and at 330° C., were evaluated by measuring optical transmission through the substrate glasses having the film formed on both sides of the substrate. The results are presented by the data of FIG. 6.

As can be inferred from FIG. 6 the four films exhibit relatively uniform optical absorption and high absorption coefficients in the visible part of 400-750 nm of the electromagnetic spectrum. The films also looked visibly dark. The average thickness of each of the measured films was only about 25 nanometres (nm).

Although the adsorption reactions responsible for film growth in this example are not completely understood, test runs indicated that the chemical adsorption reactions were self-limiting to at least some extent. This resulted in very conformal and uniform films over large areas of the surface and even over complex non-planar surfaces.

### EXAMPLE 2

Absorbing films were formed on substrates according to the second embodiment of the invention (see FIG. 2). Visibly essentially transparent D263T glass substrates with a thickness of 0.3 mm (available from Schott AG, Germany) were first inserted inside the reaction space of a P400 ALD batch tool (available from Beneq OY, Finland). The substrates were planar to enable reliable optical transmission measurements. The substrates were positioned inside the reaction space such that both sides of the substrate glass were exposed (i.e. not masked) to the surrounding reaction space. In this example the carrier gas discussed above, and responsible for purging the reaction space, was nitrogen (N₂).

After preparations for loading the substrates into the ALD tool, the reaction space of the ALD tool was pumped down to underpressure and a continuous flow of carrier gas was set to achieve the processing pressure of about 1 mbar (1 hPa) and the substrates were subsequently heated to the processing temperature of 280° C. The temperature was stabilized to the processing temperature inside the reaction space by a computer controlled heating period of four to six hours.

After the processing temperature was reached and stabilized, the method moved from step 1) to the first exposure step, step a), according to FIG. 2. The pulsing sequence of a), then b), then c), then b) again, was carried out once and then repeated 1999 times before the process was ended and the substrates were ejected from the reaction space and from the ALD tool.

Exposure of the surface of the substrate to a specific chemical was carried out by switching on the pulsing valve of the P400 ALD tool controlling the flow of the chemical into the reaction space. Purging of the reaction space was carried out by closing the valves controlling the flow of precursor chemicals into the reaction space, and thereby letting only the continuous flow of carrier gas flow through the reaction space.

The pulsing sequence in this example was in detail as follows; 0.6 s exposure to H₂O, 1.5 s purge, 0.4 s exposure to TiCl₄, 2.0 s purge, 0.5 s exposure to trimethylaluminum, 2.0 s purge, 0.4 s exposure to TiCl₄, 2.0 s purge. An exposure time and a purge time in this sequence signify a time a specific pulsing valve for a specific chemical was kept open and a time all the pulsing valves for chemicals were kept closed, respectively.

The film formed in this example was evaluated by measuring optical transmission through the substrate glasses having the film formed on both sides of the substrate (sample 196 of FIG. 7). The results are presented by the data of FIG. 7. This figure also presents a comparison to transmission data obtained from a film formed according to the first embodiment of the invention (sample 191 of FIG. 7). This film was formed also at a processing temperature of 280° C. with the procedure identical to example 1, with the exception that the sequence a), then b), then c) was carried out once and then repeated 1999 times.

As can be inferred from FIG. 7 both films exhibit relatively uniform optical absorption and high absorption coefficients in the visible part of 400-750 nm of the electromagnetic spectrum. The average thickness of each of the measured films was only about 100 nanometres (nm).

Although the adsorption reactions responsible for film growth in this example are not completely understood, test runs indicated that the chemical adsorption reactions were self-limiting to at least some extent. This resulted in very conformal films over large areas of the surface and even over complex non-planar surfaces.

In the examples above the oxygen containing chemical is water, preferably de-ionized H₂O, the transition metal chemical is TiCl₄, and the organometallic chemical is trimethylaluminum Al₂(CH₃)₆, but other chemicals can also be used. The transition metal oxide of the preliminary deposit is correspondingly titanium oxide, and the first metal is aluminum from the trimethylaluminum, in the examples above.

The invention is not limited to using the aforementioned chemicals in particular and the advantages of the invention can be readily obtained by the skilled person in light of this specification also with other chemicals. The other chemicals include transition metal halides which comprise transition metal chlorides such as, titanium trichloride, zirconium tetrachloride, hafnium tetrachloride, niobium pentachloride, tantalum pentachloride, molybdenum pentachloride, and tungsten hexachloride. The transition metal chemical can also be an ethoxide comprising transition metal. The organometallic chemical can also be e.g. an organometallic including gallium or transition metals. Other examples of the oxygen containing chemical are ozone, oxygen radicals, oxygen, ethoxides, H₂O₂ and N₂O.

Although the examples above disclose methods which employ alternate pulsing of two different chemicals to form the preliminary deposit of transition metal oxide by the steps a) and b), this preliminary deposit can be formed by any suitable method, e.g. CVD, MOCVD or PVD. This preliminary deposit can then be subsequently treated by an organometallic chemical comprising first metal, such as aluminum (like in the examples above), to form the absorbing oxide comprising oxygen, the first metal and the transition metal. These modifications to the disclosed embodiments will be obvious for the skilled person in light of this specification.

As is clear for a person skilled in the art, the invention is not limited to the examples and embodiments described above but the embodiments can freely vary within the scope of the claims.

1. A method for forming a decorative coating on a substrate, the decorative coating comprising an absorbing film to attenuate the transmission of visible light through the coating, the method comprising the steps of bringing the substrate into a reaction space, and depositing the absorbing film on the substrate, wherein depositing the absorbing film on the substrate comprises the steps of
forming a preliminary deposit of transition metal oxide on the deposition surface and subsequently purging the reaction space, and
treating the deposition surface with an organometallic chemical comprising first metal such that at least a portion of the organometallic chemical reacts with at least part of the preliminary deposit and subsequently purging the reaction space, to form oxide comprising oxygen, first metal and transition metal; the steps of forming the preliminary deposit and treating the deposition surface being alternately repeated to increase absorption of the absorbing film.

2. The method of claim 1, wherein forming the preliminary deposit of transition metal oxide comprises in any order the alternating steps of,
a) exposing the deposition surface to an oxygen containing chemical such that at least a portion of the oxygen containing chemical adsorbs onto the deposition surface, and subsequently purging the reaction space, and
b) exposing the deposition surface to a transition metal chemical such that at least a portion of the transition metal chemical gets adsorbed onto the deposition surface, and subsequently purging the reaction space.

3. The method of claim 1, wherein treating the deposition surface with an organometallic chemical comprises c) exposing the deposition surface of the substrate to an organometallic chemical such that at least a portion of the organometallic chemical gets adsorbed onto the deposition surface, and subsequently purging the reaction space.

4. The method of claim 3, wherein step a) comprises exposing the deposition surface to water, step b) comprises exposing the deposition surface to titanium tetrachloride, and step c) comprises exposing the deposition surface to trimethylaluminum.

5. The method of claim 3, wherein the steps a), b), and c) are carried out in the order, first a), then b), then c), then b) again, and this sequence is repeated one or more times to increase the thickness of the film.

6. The method of claim 3, wherein the steps a), b), and c) are carried out in the order, first a), then b), then c), and this sequence is repeated one or more times to increase the thickness of the film.

7. The method of claim 3, wherein the steps a), b), and c) are carried out in the order, first a) and then b), this sequence is repeated one or more times, after which step c) is carried out.

8. The method of claim 3, wherein the steps a), b), and c) are each carried out one or more times for forming an absorbing film having a thickness between 1 nm to 2 μm on the substrate.

9. The method of claim 1, wherein the pressure in the reaction space is between 0.1 mbar and 100 mbar when the surface of the substrate is exposed to chemicals.

10. The method of claim 1, wherein the temperature of the surface of the substrate is in the range of 150° C. to 600° C., preferably in the range of 200° C. to 500° C. and most preferably in the range of 250 to 450° C., when the surface of the substrate is exposed to chemicals.

11. The method of claim 1, wherein the steps of forming the preliminary deposit and treating the deposition surface are alternately repeated less than 4000 times to form a thin absorbing film.

12. The method of claim 1, wherein the substrate is non-planar.

13. The method of claim 1, wherein the method additionally comprises the steps of,
depositing a first transparent film having a first refractive index on the absorbing film by alternately exposing the deposition surface in the reaction space to different chemicals, such that at least a portion of the chemical which the surface is exposed to adsorbs onto the surface, and
depositing a second transparent film having a second refractive index, different from the first refractive index, on the first transparent film by alternately exposing the deposition surface in the reaction space to different chemicals, such that at least a portion of the chemical which the surface is exposed to adsorbs onto the surface,
to form a thin-film interference structure on the absorbing film.

14. A decorative coating on a substrate, the decorative coating comprising an absorbing film to attenuate the transmission of visible light through the coating, the absorbing film comprising oxygen, first metal and transition metal, wherein the film is formed by forming a preliminary deposit of transition metal oxide on the deposition surface and subsequently purging the reaction space, and treating the deposition surface with an organometallic chemical comprising first metal such that at least a portion of the organometallic chemical reacts with at least part of the preliminary deposit and subsequently purging the reaction space, to form oxide comprising oxygen, first metal and transition metal; the steps of forming the preliminary deposit and treating the deposition surface being alternately repeated to increase absorption of the absorbing film.

15. The decorative coating of claim 14, wherein the first metal is aluminum.

16. The decorative coating of claim 14, wherein the transition metal is titanium.

17. The decorative coating of claim 14, wherein the coating comprises
a first transparent film having a first refractive index on the absorbing film, and
a second transparent film having a second refractive index, different from the first refractive index, on the first transparent film, to form a thin-film interference structure on the absorbing film.

18. Use of the decorative coating of claim 14 on a substrate for attenuating the transmission of visible light through the coating.

19. The use of claim 18, wherein the substrate is non-planar.

20. The use of claim 18, wherein the substrate is essentially transparent in the visible part of the electromagnetic spectrum.

21. The use of claim 18, wherein the substrate is a lens.
